(19) United States
(12) Patent Application Publication
(10) Pub. No.: US 2024/0291233 A1
(43) Pub. Date: Aug. 29, 2024

(54) Semiconductor Optical Device

(71) Applicant: Nippon Telegraph and Telephone Corporation, Tokyo (JP)

(72) Inventors: Suguru Yamaoka, Musashino-shi, Tokyo (JP); Shinji Matsuo, Musashino-shi, Tokyo (JP)

(21) Appl. No.: 18/573,028

(22) PCT Filed: Jul. 1, 2021
(86) PCT No.: PCT/JP2021/024936

§ 371 Date: Dec. 21, 2023

(51) Int. Cl. H01S 5/026; H01S 5/02; H01S 5/223

(52) U.S. Cl. CPC H01S 5/026; H01S 5/021; H01S 5/223

(57) ABSTRACT

A semiconductor optical device includes: a first cladding layer formed on a Si substrate; a core formed on the first cladding layer; and a second cladding layer formed on the first cladding layer to cover the core. A lower cladding layer including SiO2 or the like is formed on (a front surface of) the Si substrate, and the first cladding layer is formed on the lower cladding layer. The first cladding layer includes a material having thermal conductivity higher than thermal conductivity of a direct transition type semiconductor. A refractive index of the first cladding layer is higher than that of the second cladding layer and lower than that of the core. In an optical coupling region of an optical waveguide by the core, a cross-sectional shape of the core is in a state in which a substrate radiation mode appears.

### TECHNICAL FIELD

The present invention relates to a semiconductor optical device.

### BACKGROUND ART

Si photonics is a technology in which an electronic device and an optical device are integrated on a large-diameter Si substrate by CMOS technology. Since Si is an indirect transition semiconductor, the luminous efficiency is extremely low, and thus it is difficult to use Si as a light emitting device. For this reason, a group III-V compound semiconductor such as GaAs or InP that is a direct transition type semiconductor and has high luminous efficiency is used as an optical device.

For example, according to Non Patent Literature 1, as an optical device of Si photonics, it is possible to produce a laser structure on a SiO₂/Si substrate by a bonding technique of an InP substrate and a SiO₂/Si substrate. Substrate bonding techniques include hydrophilization bonding and surface activation bonding. For example, a layer including an insulating material such as SiO₂ is used for a bonding interface in the bonding.

In a membrane laser structure on a SiO₂/Si substrate, the refractive index of the Si substrate is higher than the refractive index of an upper cladding medium, and is comparable to the refractive index of an active layer medium. For this reason, to obtain high optical confinement in an active layer, a design is necessary in which the thickness of SiO₂ is set to the order of several μm and a waveguide mode is not distributed on the Si substrate. For example, the membrane laser structure on the SiO₂/Si substrate has a structure in which the active layer is sandwiched between layers of low refractive index media, so that a high optical confinement factor is obtained. For this reason, a direct modulation laser with high efficiency and low power consumption is achieved (Non Patent Literature 1).

However, in the above laser structure, since the thermal conductivity of SiO₂ is small, a heat dissipation effect in the active layer is small. For this reason, there is a problem that a temperature rise due to current injection is large, and optical output and modulation speed are saturated with a relatively small bias current.

To solve this problem, it has been proposed to produce a laser on a heat dissipation substrate having a refractive index lower than that of a core and having high thermal conductivity. For example, a laser structure using SiC having a thermal conductivity higher than that of Si or InP and a refractive index smaller than that of Si or InP as a substrate is produced, and heat dissipation characteristics of a laser active layer are improved. As a result, since more current can be injected than in a conventional structure, a direct modulation laser having a band of 60 GHz is achieved (Non Patent Literature 3).

### CITATION LIST

### Non Patent Literature

Non Patent Literature 1: T. Fujii, T. Sato, K. Takeda, K. Hasebe, T. Kakitsuka, and S. Matsuo, “Epitaxial growth of InP to bury directly bonded thin active layer on SiO2/Si substrate for fabricating distributed feedback lasers on silicon”, IET Optoelectronics, vol. 9, no. 4, pp. 151-157, 2015.
Non Patent Literature 2: W. Kobayashi, T. Ito, T. Yamanaka, T. Fujisawa, Y. Shibata, T. Kurosaki, M. Kohtoku, T. Tadokoro, and H. Sanjoh, “50-Gb/s direct modulation of a 1.3-μm InGaAlAs-based DFB laser with a ridge waveguide structure”, IEEE Journal of Selected Topics in Quantum Electronics, vol. 19, no. 4, pp. 1500908-1500908, 2013.
Non Patent Literature 3: S. Yamaoka, N.-P. Diamantopoulos, H. Nishi, R. Nakao, T. Fujii, K. Takeda, T. Hiraki, T. Tsurugaya, S. Kanazawa, H. Tanobe, T. Kakitsuka, T. Tsuchizawa, F. Koyama, and S. Matsuo, “Directly modulated membrane lasers with 108 GHz bandwidth on a high-thermal-conductivity silicon carbide substrate”, Nature Photonics, vol. 15, pp. 28-35, 2021.

### SUMMARY OF INVENTION

### Technical Problem

By the way, the laser formed on the heat dissipation substrate can be expected to have very excellent operation characteristics as a single optical device, but in the current structure, it is difficult to optically couple the optical output from the laser on the heat dissipation substrate to a Si optical waveguide embedded in SiO₂ of the SiO₂/Si substrate, and application to Si photonics is a problem.

As described above, by forming the laser on the layer having high heat dissipation, it is possible to increase an amount of current that can be injected into a semiconductor laser portion due to high heat dissipation in the active layer, so that high optical output, high speed modulation, and high temperature operation can be expected. However, application to Si photonics cannot be achieved only by having a configuration in which the laser is disposed on the heat dissipation layer. For example, it is necessary to optically couple the optical output from the laser on the layer having high heat dissipation to the optical waveguide including Si with high efficiency with a thickness of the layer having high heat dissipation of about several μm to several tens μm. However, there has been a problem that such optical coupling is not easy.

The present invention has been made to solve the above problems, and an object thereof is to more easily obtain optical coupling between an optical device and a Si optical waveguide arranged with a layer having a high heat dissipation interposed therebetween.

### Solution to Problem

A semiconductor optical device according to the present invention includes: a first cladding layer formed on a Si substrate and including a material having thermal conductivity higher than thermal conductivity of a direct transition type semiconductor; a core formed on the first cladding layer and including a direct transition type semiconductor; a second cladding layer formed on the first cladding layer to cover the core, in which a refractive index of the first cladding layer is higher than a refractive index of the second cladding layer and lower than a refractive index of the core, and in an optical coupling region of an optical waveguide by the core, a cross-sectional shape of the core is in a state in which a substrate radiation mode appears.

### Advantageous Effects of Invention

As described above, according to the present invention, it is possible to more easily obtain optical coupling between an optical device and a Si optical waveguide arranged with a layer having a high heat dissipation interposed therebetween.

### BRIEF DESCRIPTION OF DRAWINGS

FIG. 1 is a cross-sectional view illustrating a configuration of a semiconductor optical device according to an embodiment of the present invention.

FIG. 2A is a cross-sectional view illustrating a configuration of a semiconductor laser used to study heat dissipation characteristics of the semiconductor optical device according to the embodiment.

FIG. 2B is a characteristic diagram illustrating a result of studying the heat dissipation characteristics of the semiconductor optical device according to the embodiment.

FIG. 3A is a distribution diagram illustrating a result of calculation of a profile of a substrate radiation mode in an optical waveguide by a core 103 in a case where a rib structure 105 is not provided (d_{etch}=0 μm).

FIG. 3B is a distribution diagram illustrating a result of calculation of the profile of the substrate radiation mode in the optical waveguide by the core 103 in a case where the thickness of the rib structure 105 is 0.1 μm (d_{etch}=0.1 μm).

FIG. 3C is a distribution diagram illustrating a result of calculation of the profile of the substrate radiation mode in the optical waveguide by the core 103 in a case where the thickness of the rib structure 105 is 0.2 μm (d_{etch}=0.2 μm).

FIG. 4A is a distribution diagram illustrating a result of calculation of the profile of the substrate radiation mode in the optical waveguide by the core 103 in which the core width is 0.5 μm.

FIG. 4B is a distribution diagram illustrating a result of calculation of the profile of the substrate radiation mode in the optical waveguide by the core 103 in which the core width is 0.4 μm.

FIG. 4C is a distribution diagram illustrating a result of calculation of the profile of the substrate radiation mode in the optical waveguide by the core 103 in which the core width is 0.3 μm.

FIG. 5A is a distribution diagram illustrating a result of calculation of the profile of the substrate radiation mode in the optical waveguide by the core 103 in which the core width is 0.5 μm.

FIG. 5B is a distribution diagram illustrating a result of calculation of the profile of the substrate radiation mode in the optical waveguide by the core 103 in which the core width is 0.4 μm.

FIG. 5C is a distribution diagram illustrating a result of calculation of the profile of the substrate radiation mode in the optical waveguide by the core 103 in which the core width is 0.3 μm.

FIG. 6 is a cross-sectional view illustrating a configuration of another semiconductor optical device according to the embodiment of the present invention.

FIG. 7A is a distribution diagram illustrating a result of calculation of a mode profile in a case where the core width of the core 103 is 0.7 μm and the core width of a lower core 107 is 0.3 μm.

FIG. 7B is a distribution diagram illustrating a result of calculation of the mode profile in a case where the core width of the core 103 is 0.5 μm and the core width of the lower core 107 is 0.3 μm.

FIG. 7C is a distribution diagram illustrating a result of calculation of the mode profile in a case where the core width of the core 103 is 0.3 μm and the core width of the lower core 107 is 0.3 μm.

FIG. 7D is a distribution diagram illustrating a result of calculation of the mode profile in a case where the core width of the core 103 is 0.3 μm and the core width of the lower core 107 is 0.35 μm.

FIG. 7E is a distribution diagram illustrating a result of calculation of the mode profile in a case where the core width of the core 103 is 0.3 μm and the core width of the lower core 107 is 0.4 μm.

FIG. 8 is a distribution diagram illustrating calculation of mode transition from the optical waveguide by the core 103 to an optical waveguide by the lower core 107 in a case where a rib structure is not provided.

FIG. 9 is a cross-sectional view illustrating a configuration of another semiconductor optical device according to the embodiment of the present invention.

FIG. 10 is a cross-sectional view illustrating a configuration of another semiconductor optical device according to the embodiment of the present invention.

### DESCRIPTION OF EMBODIMENTS

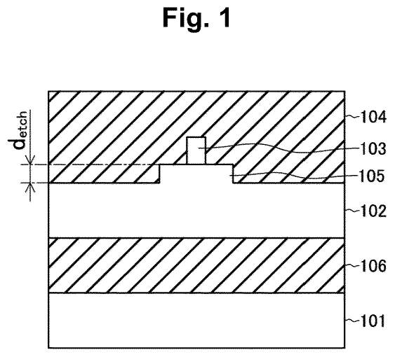

A semiconductor optical device according to an embodiment of the present invention will be described below with reference to FIG. 1. The semiconductor optical device includes: a first cladding layer 102 formed on a Si substrate 101; a core 103 formed on the first cladding layer 102; and a second cladding layer 104 formed on the first cladding layer 102 to cover the core 103. In this example, a lower cladding layer 106 including SiO₂ or the like is formed on (a front surface of) the Si substrate 101, and the first cladding layer 102 is formed on the lower cladding layer 106.

The first cladding layer 102 includes a material having thermal conductivity higher than thermal conductivity of a direct transition type semiconductor. The core 103 includes a direct transition type semiconductor. The core 103 can include, for example, a group III-V compound semiconductor such as InP or InGaAsP. The core 103 is formed to be connected to an active layer of a semiconductor laser not illustrated in FIG. 1. Laser light oscillated by the semiconductor laser is guided to an optical waveguide by the core 103.

In addition, in the semiconductor optical device, a refractive index of the first cladding layer 102 is higher than that of the second cladding layer 104 and lower than that of the core 103. The first cladding layer 102 can include, for example, SiC, AlN, GaN, diamond, or the like. The second cladding layer 104 can include SiO₂, SiOₓ, or the like.

In addition, in an optical coupling region of the optical waveguide by the core 103, a cross-sectional shape of the core 103 is in a state in which a substrate radiation mode appears. FIG. 1 illustrates a cross section in the optical coupling region of the semiconductor optical device. For example, a width of the core 103 in a planar direction of the Si substrate 101 is smaller toward the optical coupling region. The width (core width) of the core 103 is reduced, whereby the substrate radiation mode can appear. As an example, for example, the core width of the core 103 in the optical coupling region can be 0.3 μm, and the thickness can be 0.32 μm. The thickness 0.32 μm of the core 103 is an approximately upper limit value at which light having a wavelength of 1.31 μm propagating in the active layer is in a single mode with respect to the thickness direction of the active layer.

By setting the substrate radiation mode, it is possible to couple the laser light guided in the optical waveguide by the core 103 to an optical waveguide by a lower core formed under the first cladding layer 102 not illustrated in FIG. 1. The optical waveguide by the lower core disposed under the first cladding layer 102 is disposed to overlap the core 103 in the optical coupling region. For example, the lower core can include Si and be formed by being embedded in the lower cladding layer 106. Note that the optical waveguide by the lower core is disposed at a position in a range where the optical waveguide can be optically coupled to the optical waveguide by the core 103 in the optical coupling region.

In addition, in this example, the first cladding layer 102 in the optical coupling region includes a rib structure 105 thickened in a convex shape on a front surface, and the core 103 is formed on the rib structure 105. For example, the rib structure 105 can be formed by performing etching processing on the first cladding layer 102 using a resist pattern formed by a known lithography technique as a mask. An etching depth d_{etch} in this etching processing is the thickness of the rib structure 105.

By providing the rib structure 105, it becomes possible to improve optical confinement in the lateral direction of the substrate radiation mode, and perform coupling of light by the substrate radiation mode described above more efficiently. Further, in the optical coupling region, a first grating coupler is formed in the core 103, and a second grating coupler is formed in the lower core disposed under the first cladding layer 102 described above, whereby the optical coupling described above can be more efficiently achieved. The first grating coupler formed in the core 103 can radiate the laser light guided in the optical waveguide by the core 103 to the Si substrate 101 side. The light thus radiated is coupled to the second grating coupler formed in the lower core.

For example, on a substrate to be the first cladding layer 102, the core 103 and a semiconductor laser connected to the core 103 are produced, and the rib structure 105 is formed, and then SiO₂ is deposited to cover them to form the second cladding layer 104. Next, the substrate is thinned from a back surface to form the first cladding layer 102, and then bonded to the Si substrate 101 on which the lower cladding layer 106 is formed. Thus, the semiconductor optical device according to the embodiment can be produced. For example, an optical waveguide by the lower core or the like can be formed before bonding, in the lower cladding layer 106.

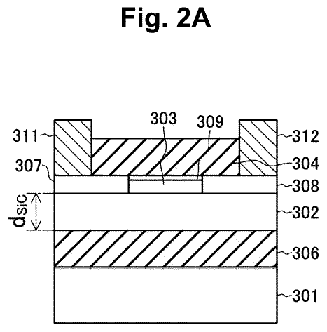

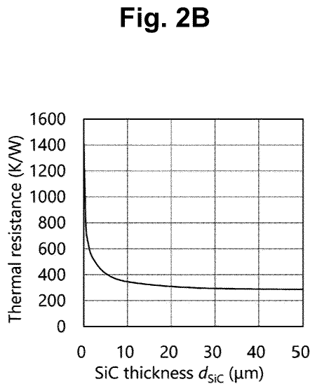

Next, a result of studying heat dissipation characteristics in above-described the configuration will be described. In this study, a semiconductor laser is used whose cross section is schematically illustrated in FIG. 2A. In this semiconductor laser, first, a lower cladding layer 306 including SiO₂ is formed on a Si substrate 301, and a first cladding layer 302 including SiC and having a thickness of d_{SiC} is formed on the lower cladding layer 306.

In addition, on the first cladding layer 302, a so-called membrane laser structure is provided including an active layer 303, a p-InP layer 307 and an n-InP layer 308 arranged sandwiching the active layer 303. The active layer 303 has, for example, a multiple quantum well structure by InGaAlAs or InGaAsP. Note that in a region sandwiched between the p-InP layer 307 and the n-InP layer 308, an upper surface of the active layer 303 is covered with a semiconductor layer 309 including non-doped InP.

In addition, a second cladding layer 304 including SiO₂ is formed on the active layer 303, the p-InP layer 307, and the n-InP layer 308. In addition, a p-electrode 311 is in ohmic contact with the p-InP layer 307, and an n-electrode 312 is in ohmic contact with the n-InP layer 308.

The active layer 303 has a core shape with a core width of 0.7 μm and a thickness of 0.33 μm. FIG. 2B illustrates d_{SiC} dependency of thermal resistance of the semiconductor laser in which the active layer length in a waveguide direction is 50 μm. Note that a heat source is disposed only in the p-InP layer 307 and has a power of 100 mW. As illustrated in FIG. 2B, it is clear that the thermal resistance value decreases as d_{SiC} increases. This indicates that, as the thickness of the first cladding layer including SiC increases, an amount of injection current for the semiconductor laser can be increased, and a modulation band can be increased by increasing a relaxation vibration frequency.

Next, a mode profile around the optical waveguide by the core 103 will be described.

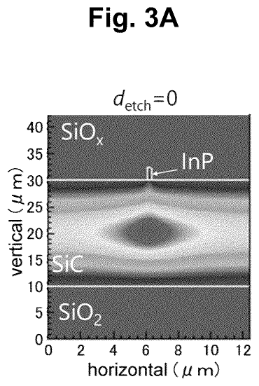

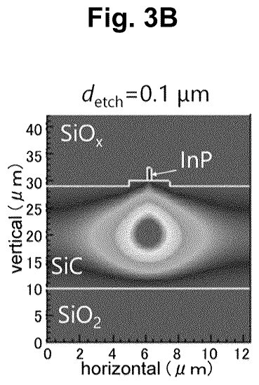

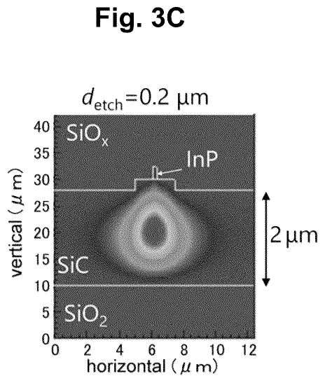

First, effects of the rib structure 105 will be described with reference to FIGS. 3A, 3B, and 3C. FIG. 3A illustrates a result of calculation of a profile of the substrate radiation mode in the optical waveguide by the core 103 in a case where the rib structure 105 is not provided (d_{etch}=0 μm). In addition, FIG. 3B illustrates a result of calculation of the profile of the substrate radiation mode in the optical waveguide by the core 103 in a case where the thickness of the rib structure 105 is 0.1 μm (d_{etch}=0.1 μm). In addition, FIG. 3C illustrates a result of calculation of the profile of the substrate radiation mode in the optical waveguide by the core 103 in a case where the thickness of the rib structure 105 is 0.2 μm (d_{etch}=0.2 μm).

In addition, the lower cladding layer 106 includes SiO₂, the first cladding layer 102 includes SiC, the core 103 includes InP, and the second cladding layer 104 includes SiOₓ. In addition, the core 103 has a core width of 0.3 μm and a thickness of 0.25 μm. In addition, the first cladding layer 102 has a thickness of 2 μm, and the lower cladding layer 106 has a thickness of 1 μm. In addition, etching processing is performed on a portion 2 μm away from a formation position of the core 103 in the planar direction to form the rib structure 105.

As illustrated in FIGS. 3A, 3B, and 3C, the waveguide mode is a substrate radiation mode. In addition, in a case where the rib structure 105 is formed, optical confinement of the first cladding layer 102 in the lateral direction by SiC is strengthened. Thus, when the rib structure 105 is used, light can be more effectively coupled to the optical waveguide by the lower core.

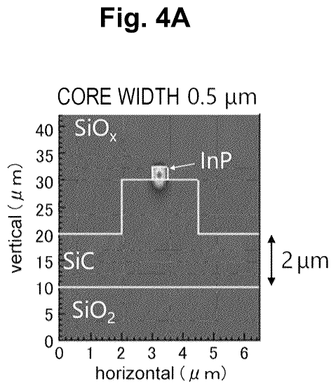

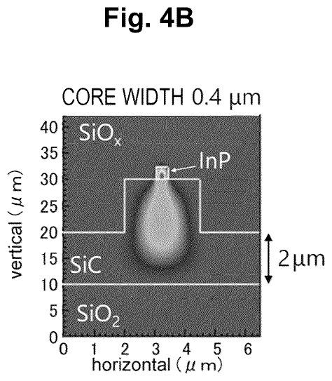

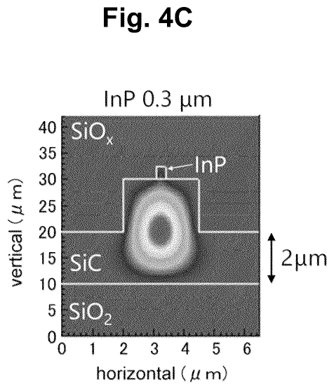

Next, a relationship between the core width of the core 103 and the substrate radiation mode will be described with reference to FIGS. 4A, 4B, and 4C. FIG. 4A illustrates a result of calculation of the profile of the substrate radiation mode in the optical waveguide by the core 103 in which the core width is 0.5 μm. FIG. 4B illustrates a result of calculation of the profile of the substrate radiation mode in the optical waveguide by the core 103 in which the core width is 0.4 μm. FIG. 4C illustrates a result of calculation of the profile of the substrate radiation mode in the optical waveguide by the core 103 in which the core width is 0.3 μm.

Note that, the lower cladding layer 106 includes SiO₂, the first cladding layer 102 includes SiC, the core 103 includes InP, and the second cladding layer 104 includes SiOₓ. In addition, the core 103 has a thickness of 0.25 μm. In addition, the first cladding layer 102 has a thickness of 2 μm, and the lower cladding layer 106 has a thickness of 1 μm. In addition, etching processing is performed on a portion 2 μm away from a formation position of the core 103 in the planar direction to form the rib structure 105, and the thickness of the rib structure 105 is 2 μm.

As illustrated in FIG. 4A, at a core width of 0.5 μm, a mode is distributed in the optical waveguide by the core 103. On the other hand, as illustrated in FIGS. 4B and 4C, the substrate radiation mode appears at core widths of 0.4 μm and 0.3 μm. Thus, by setting the core width to about 0.5 μm and gradually reducing the core width to the optical coupling region in a region that is not the optical coupling region, it is possible to gradually cause substrate radiation during mode propagation of the optical waveguide by the core 103.

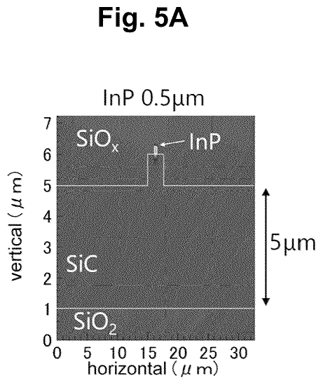

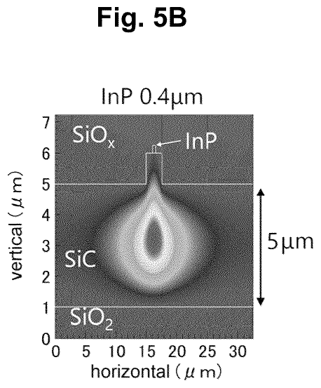

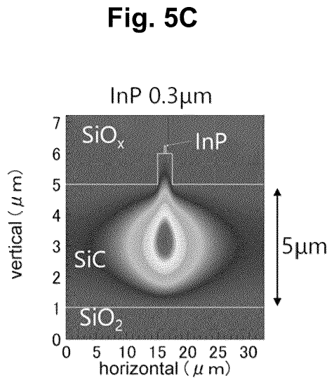

Next, the relationship between the core width of the core 103 and the substrate radiation mode in a case where the first cladding layer 102 is made thicker will be described with reference to FIGS. 5A, 5B, and 5C. In this example, the thickness of the first cladding layer 102 including SiC is set to 5 μm.

Note that FIG. 5A illustrates a result of calculation of the profile of the substrate radiation mode in the optical waveguide by the core 103 in which the core width is 0.5 μm. FIG. 5B illustrates a result of calculation of the profile of the substrate radiation mode in the optical waveguide by the core 103 in which the core width is 0.4 μm. FIG. 5C illustrates a result of calculation of the profile of the substrate radiation mode in the optical waveguide by the core 103 in which the core width is 0.3 μm.

As illustrated, even if the first cladding layer 102 is made thicker, substrate radiation appears as the core width of the core 103 is narrowed, similarly to the results illustrated in FIGS. 4A, 4B, and 4C. In addition, also in this result of calculation, it can be seen that the mode is confined in the lateral direction in the first cladding layer 102 by using the rib structure 105. Note that, in the core 103, the substrate radiation mode appears more efficiently by reduction of the thickness in addition to the width.

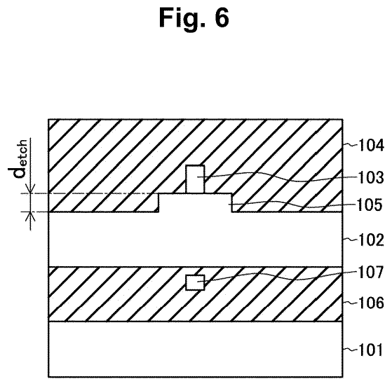

Next, optical coupling to the optical waveguide by the lower core will be described. Hereinafter, a semiconductor optical device illustrated in FIG. 6 will be described as an example. The semiconductor optical device includes the lower cladding layer 106 formed on the Si substrate 101, the first cladding layer 102 formed on the lower cladding layer 106, the core 103 formed on the first cladding layer 102, and the second cladding layer 104 formed on the first cladding layer 102 to cover the core 103. In addition, the rib structure 105 is formed in the first cladding layer 102. The configuration of these is similar to those of the semiconductor optical device described with reference to FIG. 1.

In addition, in this example, a lower core 107 is provided formed to be embedded in the lower cladding layer 106 on the Si substrate 101 under the first cladding layer 102. The lower core 107 includes Si, for example. Note that FIG. 6 illustrates a cross section in the optical coupling region of the semiconductor optical device.

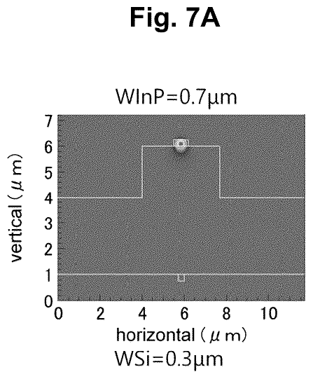

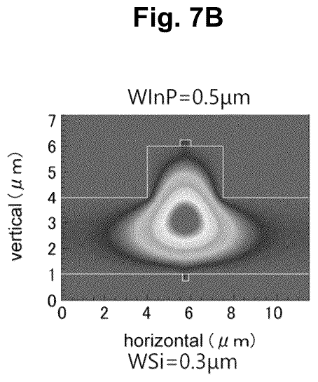

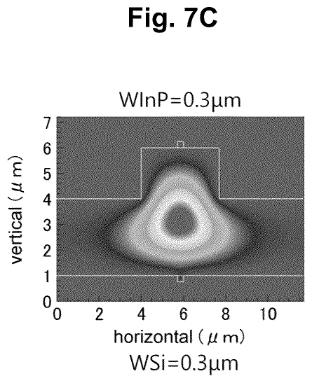

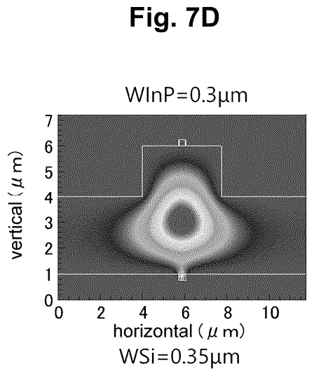

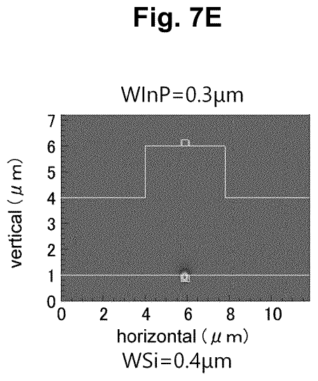

FIGS. 7A, 7B, 7C, 7D, and 7E illustrate results of calculation of the mode profile calculated by changing the core width of the core 103 and the core width of the lower core 107 for this semiconductor optical device. Note that the core 103 includes InP, the lower core 107 includes Si, the first cladding layer 102 includes SiC, the second cladding layer 104 includes SiOₓ, and the lower cladding layer 106 includes SiO₂.

FIG. 7A illustrates a result of calculation of the mode profile in a case where the core width of the core 103 is 0.7 μm and the core width of the lower core 107 is 0.3 μm. FIG. 7B illustrates a result of calculation of the mode profile in a case where the core width of the core 103 is 0.5 μm and the core width of the lower core 107 is 0.3 μm. FIG. 7C illustrates a result of calculation of the mode profile in a case where the core width of the core 103 is 0.3 μm and the core width of the lower core 107 is 0.3 μm. FIG. 7D illustrates a result of calculation of the mode profile in a case where the core width of the core 103 is 0.3 μm and the core width of the lower core 107 is 0.35 μm. FIG. 7E illustrates a result of calculation of the mode profile in a case where the core width of the core 103 is 0.3 μm and the core width of the lower core 107 is 0.4 μm.

As illustrated in FIGS. 7A, 7B, 7C, 7D, and 7E, it can be seen that the mode efficiently transitions from the optical waveguide by the core 103 to the optical waveguide by the lower core 107 by further decreasing the core width of the core 103 and the core width of the lower core 107.

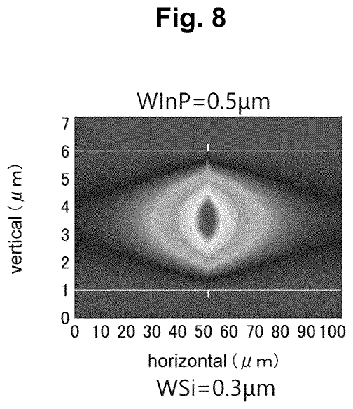

Note that FIG. 8 illustrates mode transition from the optical waveguide by the core 103 to the optical waveguide by the lower core 107 in a case where the rib structure is not provided. In this calculation, the core width of the core 103 is 0.5 μm, and the core width of the lower core 107 is 0.3 μm. As compared with a case where the rib structure is used, the mode in the first cladding layer 102 is widened in the lateral direction. For this reason, the efficiency of mode transition from the optical waveguide by the core 103 to the optical waveguide by the lower core 107 is reduced.

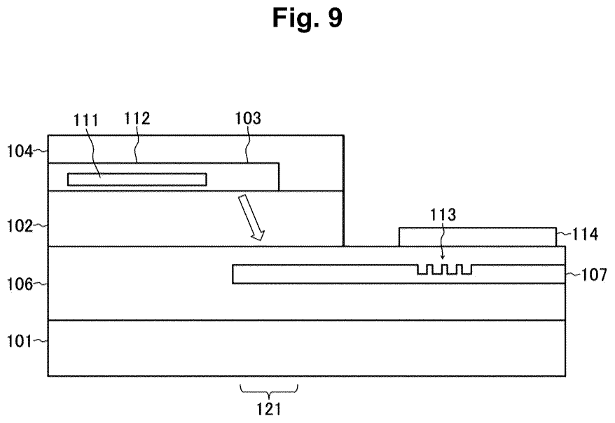

Next, a configuration in which semiconductor lasers are integrated will be described with reference to FIG. 9. FIG. 9 schematically illustrates a cross section parallel to the waveguide direction. A semiconductor laser 112 including an active layer 111 having a multiple quantum well structure is formed on the first cladding layer 102, and the core 103 is formed to be optically connected to the semiconductor laser 112. The semiconductor laser 112 is, for example, a distributed feedback (DFB) laser. The semiconductor laser 112 is covered with the second cladding layer 104 together with the core 103. The core width of the core 103 gradually decreases from a coupling position with the semiconductor laser 112 to an optical coupling region 121.

In addition, in the lower cladding layer 106, the lower core 107 is formed to vertically overlap with the core 103 in the optical coupling region 121. The lower core 107 extends from the optical coupling region 121 in a direction in which the lower core 107 is away from the semiconductor laser 112. In a region where the lower core 107 extends, for example, the first cladding layer 102 and the second cladding layer 104 are not formed.

In the optical waveguide by the core 103 in the optical coupling region 121 having a small core width of, for example, 0.3 μm, the waveguide mode becomes the substrate radiation mode, and it is possible to couple to the optical waveguide by the lower core 107. In addition, in the optical coupling region 121, the core width of the lower core 107 is, for example, 0.3 μm, which is smaller than that of other regions. For this reason, the waveguide mode transitions from the optical waveguide by the core 103 to the optical waveguide by the lower core 107.

In addition, the optical feedback portion 113 is formed at a predetermined position in the extending region away from the optical coupling region 121 in the waveguide direction of the lower core 107. The optical feedback portion 113 can be, for example, a DBR by a diffraction grating, or a gap. In addition, the optical feedback portion 113 can be a portion according to Fresnel reflection in the optical waveguide by the lower core 107.

The semiconductor laser 112 interacts with a Fabry-Perot resonance mode formed by the optical feedback portion 113, and a resonance phenomenon between photons (Photon-photon resonance (PPR)) occurs under a condition that a phase matching condition is satisfied. By this PPR, the band of the semiconductor laser 112 can be widened.

In addition, it is possible to control a phase by providing a heater 114 on the lower cladding layer 106 at a position where the optical feedback portion 113 is formed and adjusting a temperature in the optical feedback portion 113. For example, since the lower cladding layer 106 including SiO₂ has low thermal conductivity, the temperature in the optical feedback portion 113 can be efficiently adjusted.

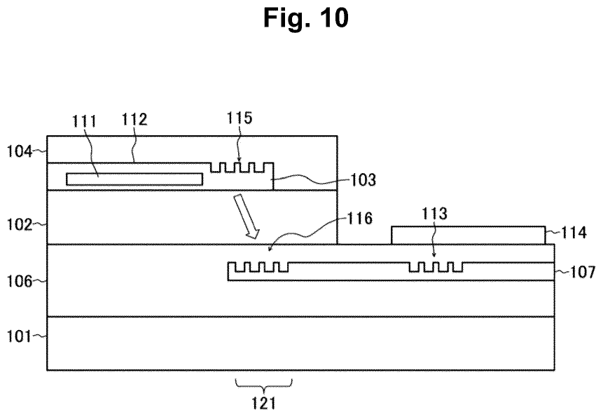

In addition, as illustrated in FIG. 10, in the optical coupling region 121, a first grating coupler 115 is formed in the core 103 and a second grating coupler 116 is formed in the lower core 107, whereby the above-described optical coupling can be achieved more efficiently. The first grating coupler 115 formed in the core 103 can radiate the laser light guided in the optical waveguide by the core 103 to the Si substrate 101 side. The radiated light is coupled to the second grating coupler 116 formed in the lower core 107. The coupled laser light is guided in a direction in which the lower core 107 extends.

As described above, according to the semiconductor optical device according to the embodiment, laser light from the semiconductor laser 112 formed on the first cladding layer 102 having high heat dissipation can be coupled to the Si optical waveguide by the lower core 107 via the optical waveguide by the core 103, and a laser operating in a wide band and at a high temperature can be applied to Si photonics.

As described above, in the present invention, the first cladding layer including a material having thermal conductivity higher than that of the direct transition type semiconductor is formed on the Si substrate, the core including the direct transition type semiconductor is formed on the first cladding layer, the refractive index of the first cladding layer is lower than that of the core, and in the optical coupling region of the optical waveguide by the core, the cross-sectional shape of the core is in a state in which the substrate radiation mode appears. As a result, according to the present invention, it is possible to more easily obtain optical coupling between an optical device and a Si optical waveguide arranged with a layer having a high heat dissipation interposed therebetween.

Note that the present invention is not limited to the embodiments described above, and it is obvious that many modifications and combinations can be made by those skilled in the art within the technical idea of the present invention.

### REFERENCE SIGNS LIST

101 Si substrate
102 first cladding layer
103 core
104 second cladding layer
105 rib structure
106 lower cladding layer

1. A semiconductor optical device comprising:
a first cladding layer formed on a Si substrate and including a material having thermal conductivity higher than thermal conductivity of a direct transition type semiconductor;
a core formed on the first cladding layer and including a direct transition type semiconductor;
a second cladding layer formed on the first cladding layer to cover the core, wherein
a refractive index of the first cladding layer is higher than a refractive index of the second cladding layer and lower than a refractive index of the core, and
in an optical coupling region of an optical waveguide by the core, a cross-sectional shape of the core is in a state in which a substrate radiation mode appears.

2. The semiconductor optical device according to claim 1, wherein
the first cladding layer in the optical coupling region has a rib structure thickened in a convex shape on a front surface, and
the core is formed on the rib structure.

3. The semiconductor optical device according to claim 1, wherein
a width of the core in a planar direction of the Si substrate is smaller toward the optical coupling region.

4. The semiconductor optical device according to claim 1, further comprising:
a lower core formed on the Si substrate under the first cladding layer, wherein
the optical waveguide by the core is disposed to be enabled to optically couple to the optical waveguide by the lower core, in the optical coupling region.

5. The semiconductor optical device according to claim 4, further comprising:
a first grating coupler formed in the core in the optical coupling region; and
a second grating coupler formed in the lower core in the optical coupling region.

6. The semiconductor optical device according to claim 2, wherein
a width of the core in a planar direction of the Si substrate is smaller toward the optical coupling region.

7. The semiconductor optical device according to claim 2, further comprising:
a lower core formed on the Si substrate under the first cladding layer, wherein
the optical waveguide by the core is disposed to be enabled to optically couple to the optical waveguide by the lower core, in the optical coupling region.

8. The semiconductor optical device according to claim 3, further comprising:
a lower core formed on the Si substrate under the first cladding layer, wherein
the optical waveguide by the core is disposed to be enabled to optically couple to the optical waveguide by the lower core, in the optical coupling region.
